(19) United States
(12) Patent Application Publication
(10) Pub. No.: US 2015/0146062 A1
(43) Pub. Date: May 28, 2015

(54) SOLID-STATE IMAGING DEVICE

(71) Applicant: KABUSHIKI KAISHA TOSHIBA, Tokyo (JP)

(72) Inventor: Nagataka TANAKA, Oita Oita (JP)

(21) Appl. No.: 14/541,925

(22) Filed: Nov. 14, 2014

(30) Foreign Application Priority Data
Nov. 28, 2013 (JP) 2013-246751

(51) Int. Cl. H04N 5/369; H04N 5/335; H04N 5/378

(52) U.S. Cl. CPC H04N 5/3696; H04N 5/378; H04N 5/3355
USPC 348/302

(57) ABSTRACT

A solid-state imaging device includes a first chip and a second chip. The first chip includes a pixel array in which a plurality of photodiodes corresponding to each pixel of a captured image is disposed in a two-dimensional array shape. Each photodiode generates a pixel signal corresponding to a signal charge generated by the photoelectric conversion of the photodiode. The first chip is stacked on the second chip that includes a memory storing the pixel signals generated from the first chip, where the memory is located outside a projection region formed by projecting the pixel array and in a thickness direction of the first chip.

### CROSS-REFERENCE TO RELATED APPLICATION

This application is based upon and claims the benefit of priority from Japanese Patent Application No. 2013-246751, filed Nov. 28, 2013, the entire contents of which are incorporated herein by reference.

### FIELD

Embodiments described herein relate generally to a solid-state imaging device.

### BACKGROUND

In the related art, there is a solid-state imaging device that uses bonding and stacking of a first chip and a second chip to enable miniaturization. The first chip includes a pixel array in which a plurality of photoelectric transducers (photodiodes) is disposed in a two-dimensional array. The second chip includes a storage circuit such as a memory device.

However, in the solid-state imaging device, if light penetrating the pixel array is transmitted to the storage circuit, the information stored in the storage circuit may be rewritten/corrupted by the irradiation of the light.

### DESCRIPTION OF THE DRAWINGS

FIG. 1 is a block diagram schematically illustrating a configuration of a digital camera including a solid-state imaging device according to an embodiment.

FIG. 2 is a block diagram schematically illustrating a configuration of the solid-state imaging device according to the embodiment.

FIG. 3 is a perspective view illustrating a configuration of the solid-state imaging device according to the embodiment.

FIG. 4 is a cross-sectional view taken along line A-A′ schematically illustrating the solid-state imaging device illustrated in FIG. 3.

FIG. 5 is an exploded perspective view illustrating an arrangement of components of the solid-state imaging device according to the embodiment.

FIG. 6 is an exploded perspective view illustrating an arrangement of components of a solid-state imaging device according to Modified Example 1 of the embodiment.

FIG. 7 is an exploded perspective view illustrating an arrangement of components of a solid-state imaging device according to Modified Example 2 of the embodiment.

### DETAILED DESCRIPTION

Embodiments provide a solid-state imaging device that does not allow information stored in a memory to be rewritten by light penetrating an attached pixel array.

In general, according to one embodiment, a solid-state imaging device includes a first chip in a stacked arrangement with a second chip. The first chip includes a pixel array in which a plurality of photodiodes are disposed in a two-dimensional array, and wherein each photodiode generates a pixel signal corresponding to a charge generated by photoelectric conversion in the photodiode—that is, the pixel signal corresponds to the intensity of light incident on the photodiode. The second chip includes a memory unit configured to store the pixel signals generated by the plurality of photodiodes on the first chip. The memory unit is located outside a projection region, which is defined by a projection, in a stacking direction of the first and second chips, of the area of the pixel array onto the surface of second chip.

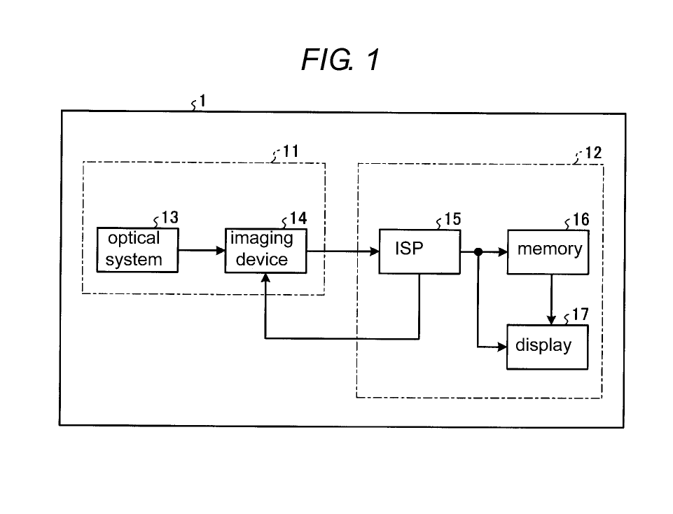

A solid-state imaging device according to the embodiment is described in detail with reference to the accompanying drawings. Further, the disclosure is not limited to the embodiment. FIG. 1 is a block diagram schematically illustrating a configuration of a digital camera 1 including a solid-state imaging device 14 according to the embodiment. As illustrated in FIG. 1, the digital camera 1 includes a camera module 11 and a post-stage processing section 12.

The camera module 11 includes an imaging optical system 13 and the solid-state imaging device 14. The imaging optical system 13 captures light from an object and forms an object image. The solid-state imaging device 14 captures the object image formed by the imaging optical system 13, and sends a pixel signal corresponding to each pixel of a captured image to the post-stage processing section 12. In addition to the digital camera 1, the camera module 11 can be applied to, for example, an electronic apparatus such as a portable terminal (e.g., smart phone) including a camera.

The post-stage processing section 12 includes an Image Signal Processor (ISP) 15, a memory unit 16, and a display unit 17. The ISP 15 performs signal processing on the pixel signal sent from the solid-state imaging device 14. The ISP 15 performs a quality improving process such as a noise removing process, a defective pixel correction process, and a resolution conversion process.

Then, the ISP 15 sends the pixel signal after the signal processing to the memory unit 16, the display unit 17, and the solid-state imaging device 14 in the camera module 11. The pixel signal that is fed back from the ISP 15 to the camera module 11 is used for the adjustment and the control of the solid-state imaging device 14.

The memory unit 16 stores the pixel signal input from the ISP 15 as an image. In addition, the memory unit 16 outputs the pixel signal of the stored image to the display unit 17 corresponding to an operation of a user or the like. The display unit 17 displays the image according to the pixel signal input from the ISP 15 or the memory unit 16. The display unit 17 is, for example, a liquid crystal display.

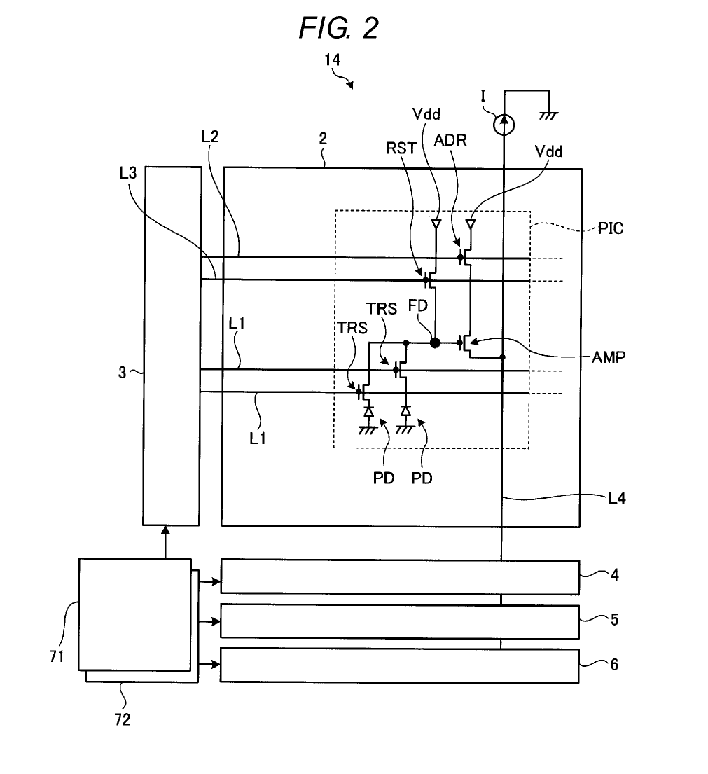

Next, the solid-state imaging device 14 included in the camera module 11 is described with reference to FIG. 2. FIG. 2 is a block diagram schematically illustrating a configuration of the solid-state imaging device 14 according to the embodiment. Here, a case is described in which the solid-state imaging device 14 is a so-called backside irradiation-type Complementary Metal Oxide Semiconductor (CMOS) image sensor, which has a wiring layer formed on a side opposite to a surface to which the light is incident.

Further, the solid-state imaging device 14 according to the embodiment is not limited to the backside irradiation-type CMOS image sensor, and may be any image sensor such as a front side irradiation-type CMOS image sensor, or a Charge Coupled Device (CCD) image sensor.

As illustrated in FIG. 2, the solid-state imaging device 14 includes a pixel array 2, a perpendicular selection circuit (hereinafter referred to as “Vertical Shift Register (VSR) 3”), a signal processing circuit (hereinafter referred to as a “Correlated Double Sampling/Analog to Digital Converter (CDS/ADC) 4”), a memory unit 5 (also referred to as “memory 5”), a horizontal selection circuit (hereinafter referred to as “Horizontal Shift Register (HSR) 6”), and Timing Generators (TG) 71 and 72.

In the pixel array 2, a plurality of photodiodes PD, each ultimately corresponding to pixels of the captured image, are disposed in a two-dimensional array shape in the horizontal direction (line direction) and the vertical direction (column direction). In FIG. 2, a circuit element corresponding to one pixel, which is a unit pixel PIC of the captured image, is selectively illustrated. According to the embodiment, a case in which the unit pixel PIC includes two (2) photodiodes PD is described, but in other embodiments one photodiode PD may be included in the unit pixel PIC, or three (3) or more photodiodes PD may be included in the unit pixel PIC.

Each of the unit pixels PIC includes two (2) photodiodes PD (each separately labeled “PD” in FIG. 2), two transfer transistors TRS (each separately labeled “TRS” in FIG. 2), a floating diffusion FD (floating diffusion node), an amplification transistor AMP, a reset transistor RST, and an address transistor ADR.

Respective photodiodes PD have cathodes that are connected to the ground and anodes that are connected to sources of the transfer transistors TRS. Each drain of the two transfer transistors TRS is connected to one floating diffusion element FD.

In the respective transfer transistors TRS, gate electrodes are connected to the VSR 3 through signal lines L1. Then, when the transfer signals are sent to the gate electrodes, the respective transfer transistors TRS transfer signal charges subjected to the photoelectric conversion by the photodiodes PD to the floating diffusion FD. The source of the reset transistor RST is connected to the floating diffusion FD.

In addition, a gate electrode of the reset transistor RST is connected to the VSR 3 through a signal line L3, and a drain is connected to a power supply voltage line Vdd. If the reset signal is sent to the gate electrode before the signal charges are transferred to the floating diffusion FD, the reset transistor RST resets the potential of the floating diffusion FD to the potential of the power supply voltage.

Continuing with FIG. 2, the gate electrode of the amplification transistor AMP is connected to the floating diffusion FD. In the amplification transistor AMP, the drain is connected to the source of the address transistor ADR, and the source is connected to a signal line L4. One end of the signal line L4 is connected to the CDS/ADC 4, and the other end is connected to the ground through a current source I.

The amplification transistor AMP transmits the pixel signal corresponding to the electric charge transferred to the floating diffusion FD to the CDS/ADC 4. That is, the amplification transistor AMP transfers the pixel signal obtained by amplifying the signal charge generated by the two photodiodes PD included in the unit pixel PIC to the CDS/ADC 4. In addition, the gate of the address transistor ADR is connected to the VSR 3 through a signal line L2, and its drain is connected to the power supply voltage line Vdd.

The TG 71 is a processing section that generates a pulse signal that becomes a timing reference for the VSR 3. The VSR 3 is a processing section that sequentially selects photodiodes to read signal charges from the plurality of photodiodes PD disposed in the two-dimensional array (matrix) shape in the line unit.

Specifically, the VSR 3 first resets the floating diffusion FD by transmitting the reset signal to the gate electrode of the reset transistor RST through the signal line L3. Next, the VSR 3 transfers the signal charges from the photodiodes PD to the floating diffusion FD by transmitting the transfer signal to gate electrode of the transfer transistors TRS and TRS through the signal lines L1.

Thereafter, the VSR 3 sends the pixel signal from the selected unit pixel PIC to the CDS/ADC 4 by transmitting a selection signal to the gate electrode of the address transistor ADR through the signal line L2.

The TG 72 is a processing section that generates a pulse signal that becomes a timing reference for the CDS/ADC 4, the memory 5, and the HSR 6. The CDS/ADC 4 is a processing section that outputs the converted digital pixel signal to the memory 5 by removing noise by correlated double sampling of the pixel signal input from the pixel array 2, and converting the analog pixel signal after removing the noise into a digital pixel signal.

The memory 5 is a volatile information storage device that temporarily stores the pixel signal generated from the CDS/ADC 4. According to the embodiment, the area occupied by the memory 5 is decreased by employing, for example, a Dynamic Random Access Memory (DRAM) as the memory 5, compared to employing other memories such as a Static Random Access Memory (SRAM).

The HSR 6 is a processing section that sends the pixel signal to the ISP 15 in FIG. 1 by reading the pixel signal from the memory 5 for each horizontal scan line of the captured image. In this manner, in the solid-state imaging device 14, the plurality of photodiodes PD disposed in the pixel array 2 perform photoelectric conversion on the incident light into the signal charges in the amount corresponding to the amount of the received light, accumulates the signal charges. An image is captured by reading the signal charges accumulated in the photodiodes PD as pixel signals.

In the solid-state imaging device 14, when the pixel array 2 and the memory 5 are provided on one chip, the memory 5 has an area that is the same size as that of the pixel array 2. A heat treatment is performed at a relatively high temperature in the manufacturing procedure so that the pixel array 2 suppresses the generation of leakage current in the photodiodes or the floating diffusion FD.

Meanwhile, it is necessary to employ a latest design rules to form a very minute circuit element, under which the memory 5 has an area much smaller than that of the pixel array 2. However, the very minute circuit element that is formed using the latest design rules has low resistance to the heat treatment.

Accordingly, when the pixel array 2 and the memory 5 are provided on one chip, the latest design rule may not employed for the memory 5, and as a result, the memory 5 having the area that is the same size as that of the pixel array 2 is formed on the chip. Therefore, the area of the chip becomes large.

Here, according to the embodiment, the pixel array 2 and the memory 5 are provided on different chips, and the two chips are stacked so that the exclusive area of the solid-state imaging device 14 is decreased. Further, the information stored in the memory 5 is prevented from being rewritten by the light penetrating the pixel array 2 by devising the arrangement position of the memory 5 on the chip.

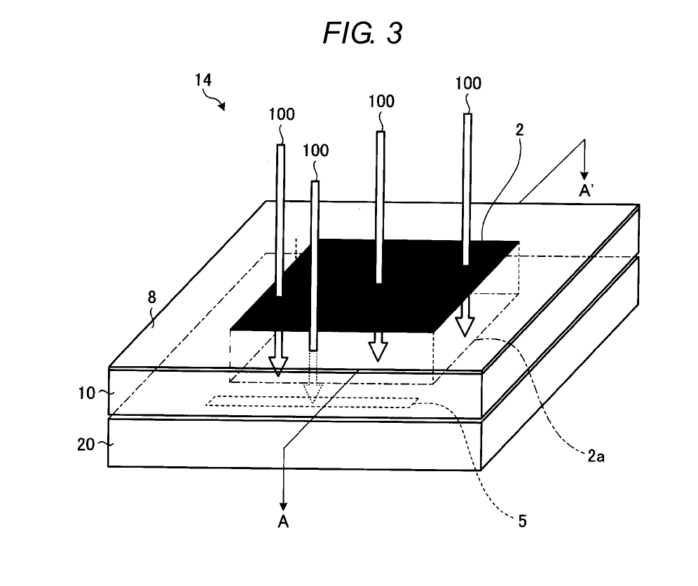

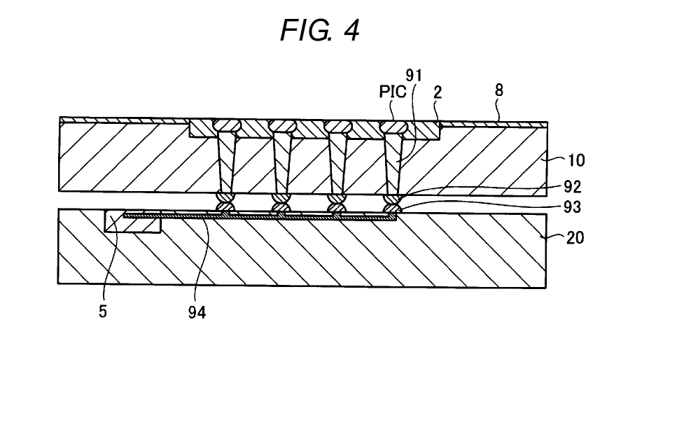

Next, the configuration of the solid-state imaging device 14 that may decrease the exclusive area and the negative influence of the penetrating light is described with reference to FIGS. 3 and 4. FIG. 3 is a perspective view illustrating a configuration of the solid-state imaging device 14 according to the embodiment and FIG. 4 is a cross-sectional view taken along line A-A′ schematically illustrating the solid-state imaging device 14 illustrated in FIG. 3.

Referring to FIG. 3, the figure depicts a partially transparent view so that an arrangement position of the memory 5 is easily understood. In addition, the pixel array 2 and the memory 5 among the components of the solid-state imaging device 14 are selectively illustrated in FIGS. 3 and 4.

As depicted in FIG. 3, the solid-state imaging device 14 includes a first chip 10 on which the pixel array 2 is provided, in the center, and a second chip 20 on which the memory 5 is provided and the first chip 10 is stacked. That is, the solid-state imaging device 14 has a stacked structure in which the first chip 10 is mounted on the second chip 20 in a connected manner. The first and second chips are in a stacked arrangement with each other in which the stacking direction, as depicted in FIG. 3, corresponds to the up-down page direction. Therefore, the solid-state imaging device 14 decreases the projected area occupied by device compared to the case in which the pixel array 2 and the memory 5 are provided on one chip in a side-by-side arrangement.

In this manner, in the first chip 10, since the pixel array 2 is provided in the center, an imaging lens having substantially the same area as that of the first chip 10 may be provided on the central region of the first chip 10. Therefore, it is possible to match the central position of the imaging lens and the central position of the pixel array 2, and it is possible to cause the entire light receiving surface of the pixel array 2 to function as a light receiving region.

Since the solid-state imaging device 14 may cover substantially the same area as the area of the imaging lens, it is possible to decrease the overall size of the apparatus in which the solid-state imaging device 14 is disposed.

In addition, in the solid-state imaging device 14, the memory 5 is provided on the second chip 20, which is different from the first chip 10 on which the pixel array 2 is provided. The manufacturing procedure for the pixel array 2 may include a plurality of heat treatment steps/processes. These heat treatments would adversely affect a memory unit (e.g., memory 5) formed on the same chip as the pixel array 2. The sensitivity of a memory unit to heating and heat cycling is especially high for those memory units having extremely small features (such as those memory units produced using the latest design rules). However, since memory 5 is not located on the same chip as pixel array 2, the heating steps used to fabricate pixel array 2 are not relevant to memory 5 on second chip 20. Therefore, the latest design rules may be employed in the formation of the memory 5. Accordingly, according to the solid-state imaging device 14, since the area of the memory 5 can be made smaller than the area of the pixel array 2, it is possible to decrease the area occupied by the second chip 20.

In addition, since the solid-state imaging device 14 may employ a DRAM having a simpler circuit structure and a smaller circuit area than SRAM, as the memory 5, it is possible to further decrease the area occupied by the second chip 20.

However, in a memory that stores information by causing a capacitor to hold electric charges in the same manner as DRAM, when strong light such as sun light or cosmic rays is transmitted to the capacitor, the stored information may be rewritten/corrupted by the irradiation.

Here, the memory 5 of the solid-state imaging device 14 is provided only outside a projection region 2a formed by projecting the pixel array 2 in the thickness direction of the first chip 10, to the upper surface of the second chip 20. Further, the region other than the region of the pixel array 2 on the upper surface of the first chip 10 is covered with a light shielding film 8.

Therefore, in the solid-state imaging device 14, even if light 100 incident to the pixel array 2 penetrates the first chip 10 and reaches the second chip 20, the light 100 is only transmitted to the aforementioned projection region 2a, and is not transmitted to the memory 5 (due to the presence of light shielding film 8).

Further, because the light 100 transmitted to the outside of the pixel array 2 is blocked by the light shielding film 8, the light 100 is not transmitted to the memory 5, which located outside of the projection region 2a. Accordingly, in the solid-state imaging device 14, the information of the pixel signal stored in the memory 5 will not be rewritten by the light 100.

In addition, as illustrated in FIG. 4, the first chip 10 includes a plurality of through electrodes (for example, Through Silicon Via (TSV)) 91 that penetrate the first chip 10 in the thickness direction and may be used to output pixel signals to the second chip. The respective through electrodes 91 makes up a portion of the signal line L4 illustrated in FIG. 2.

The first ends of through electrodes 91 are respectively connected to unit pixels PIC of the pixel array 2, specifically, to sources of the amplification transistors AMP in the unit pixels PIC, and the second ends are respectively connected to bumps 92 provided on the opposite side of the light receiving surface of the first chip 10. Among the plurality of unit pixels PIC included in the pixel array 2, four unit pixels PIC are selectively illustrated in FIG. 4.

In addition, the second chip 20 includes bumps 93 on positions that face the bumps 92 of the first chip 10. The second chip 20 also includes a wiring layer 94 connecting the respective bumps 93 to the CDS/ADC 4 (see FIG. 2), the memory 5, and the HSR 6. The first chip 10 and the second chip 20 are electrically connected to each other by welding the bumps 92 and 93 facing to each other.

Therefore, the solid-state imaging device 14 may shorten the time required to obtain the output of the pixel signals from the pixel array 2 compared to a case in which the pixel array 2 and the memory 5 are provided on one chip.

Specifically, if the pixel array 2 and the memory 5 are provided on one chip, the output of the pixel signals from the pixel array 2 is sequentially performed line-by-line, by selecting a column of one line (i.e., row) of the unit pixels PIC from the unit pixels PIC disposed in the matrix shape.

In contrast, the solid-state imaging device 14 may output the pixel signals from all the unit pixels PIC at once by transmitting the transfer signals and the selection signals from the VSR 3 to all the unit pixels PIC at the same time. Accordingly, the solid-state imaging device 14 may shorten the time required for the output of the pixel signals from the pixel array 2 compared to the case in which the pixel array 2 and the memory 5 are provided on one chip.

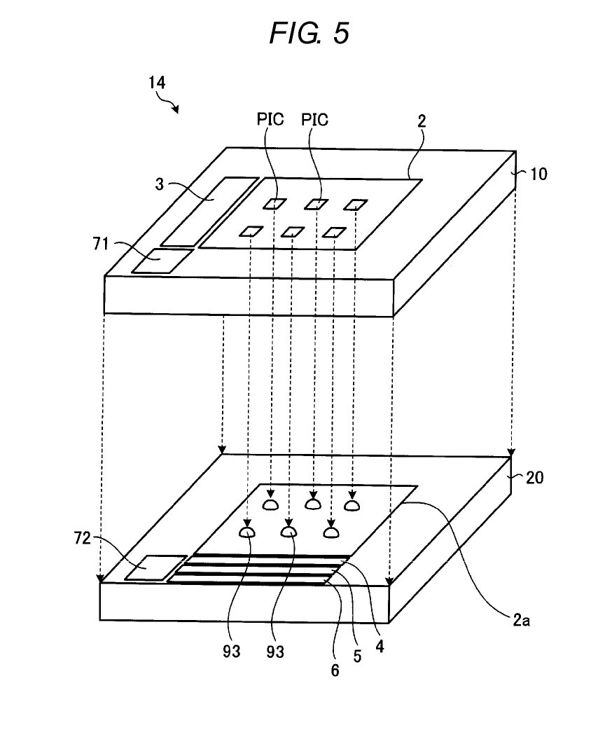

Next, the arrangement of respective components in the solid-state imaging device 14 is described with reference to FIG. 5. FIG. 5 is an exploded perspective view illustrating the arrangement of the components of the solid-state imaging device 14 according to the embodiment. Further, FIG. 5 selectively illustrates six unit pixels PIC among the plurality of unit pixels PIC included in the pixel array 2, the number of unit pixels PIC is not limited to six, but may be any appropriate number selected, for example, to correspond to an intended imaging resolution.

In addition, in the description below, among the components illustrated in FIG. 5, the same components with the components illustrated in FIG. 2 or 3 are denoted by the same reference numerals illustrated in FIG. 2 or 3, and the detailed descriptions thereof are omitted.

As illustrated in FIG. 5, the first chip 10 is provided with the pixel array 2 in the center of the first chip 10, and the VSR 3 to one side of the pixel array 2, specifically, on the side in the line direction (i.e., row direction) of the unit pixels PIC disposed in the matrix shape. In addition, the first chip 10 is provided with the TG 71 on a corner outside of the region in which the pixel array 2 is provided. As depicted in this embodiment, the corner is one the same side as the VSR 3 such that TG 71 and VSR 3 are adjacent in the column direction.

In FIG. 5, the second chip 20 is provided with the aforementioned bumps 93 inside of the projection region 2a formed by the projection of the pixel array 2 area in the thickness direction of the first chip 10 onto the second chip 20. In addition, the second chip 20 is provided with the CDS/ADC 4, the memory 5, and the HSR 6 outside of the projection region 2a, specifically, as depicted in FIG. 5 along the lower edge of the second chip 20 extending in the column direction (left-right page direction in FIG. 5).

In this manner, the second chip 20 is provided with the CDS/ADC 4 on a position nearer to the projection region 2a, such the CDS/ADC 4 is interposed between the memory 5 and the pixel array 2 (or projection region 2a). Therefore, even if the light diagonally penetrates the pixel array 2, and thus leaks beyond the projection region 2a such obliquely incident light will not reach the memory 5, but rather strike the CDS/ADC 4.

Accordingly, even if the light is diagonally incident to the pixel array 2, the solid-state imaging device 14 may prevent the memory 5 from being rewritten by the incident light.

In addition, the second chip 20 is provided with the TG 72 on the corner portion outside the projection region 2a. In this manner, since the solid-state imaging device 14 is provided with the TG 71 on the first chip 10 and the TG 72 on the second chip 20, the areas occupied by the first chip 10 and the second chip 20 may be smaller compared with the case in which the TG 71 and the TG 72 are provided on one chip.

As described above, the solid-state imaging device according to the embodiment includes the first chip which has the pixel array and the second chip on which the first chip is stacked, and which has the memory outside of the projection region formed by projecting the pixel array in the thickness direction of the first chip.

Since the solid-state imaging device according to the embodiment may suppress the light penetrating the pixel array from being transmitted to the memory, the solid-state imaging device may prevent the information stored in the memory from being rewritten by the light penetrating through pixel array.

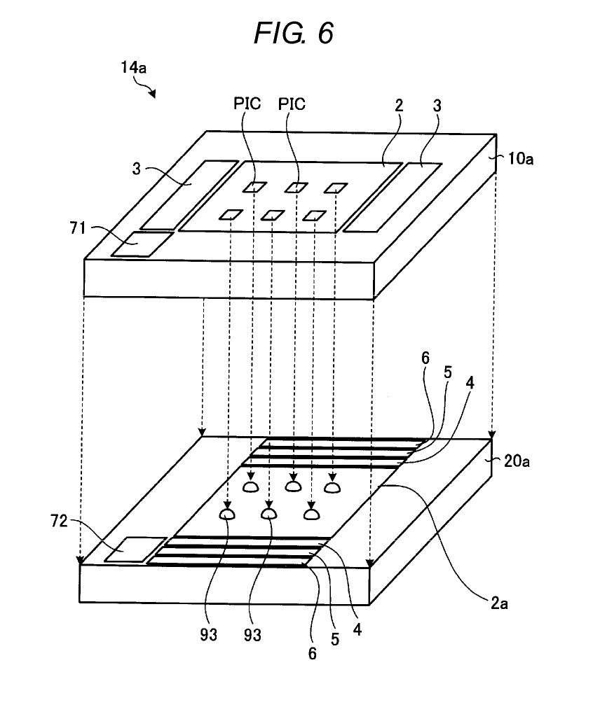

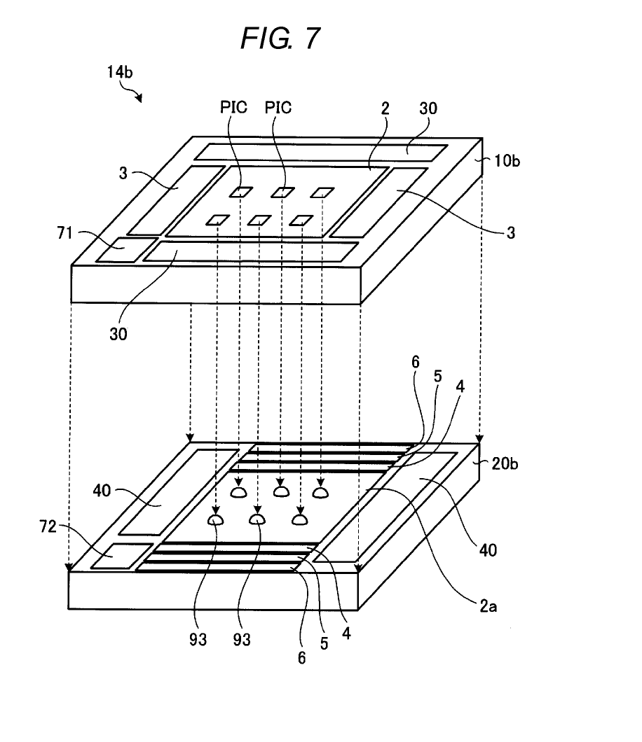

Further, the configuration of the solid-state imaging device 14 according to the embodiment described above is an example, and various modifications are possible and contemplated. Next, solid-state imaging devices 14a and 14b are described with reference to FIGS. 6 and 7.

FIG. 6 is an exploded perspective view illustrating an arrangement of components of the solid-state imaging device 14a according to Modified Example 1, and FIG. 7 is an exploded perspective view illustrating an arrangement of components of the solid-state imaging device 14b according to Modified Example 2. Further, in the description below, among the components illustrated in FIGS. 6 and 7, the same components with the components illustrated in FIG. 5 are denoted by the same reference numerals used in FIG. 5, and the detailed descriptions of repeated elements are omitted.

As illustrated in FIG. 6, a first chip 10a of the solid-state imaging device 14a includes VSRs 3 on two opposing sides (e.g., page-left and page-right sides in FIG. 6) of the pixel array 2 with the pixel array 2 interposed therebetween. Specifically, the VSRs 3 are disposed on both ends of the pixel array 2 in the line direction (row direction) of the unit pixels PIC disposed in the matrix shape.

The two VSRs 3 respectively send the transfer signals and the selection signals to the half of the unit pixels PIC positioned nearer to the respective one of the VSRs 3. Therefore, it is possible to shorten the time from the output of the transfer signals and the selection signals from the VSRs 3 to the respective unit pixels PIC.

Specifically, the time required for the transmission of the transfer signals and the selection signals becomes longer as the wiring capacitance of the signal lines L1 and L2 (see FIG. 2) from the VSRs 3 to the respective unit pixels PIC becomes greater. Here, in the solid-state imaging device 14a, the transfer signals and the selection signals are output to the unit pixels PIC provided on the right half region in the pixel array 2, for example, by the VSR 3 provided on the right side of the pixel array 2. Then, the transfer signals and the selection signals are output to the unit pixels PIC provided on the left half region in the pixel array 2 by the VSR 3 on the left side of the pixel array 2.

Therefore, in the solid-state imaging device 14a, since the lengths of the signal lines L1 and L2 from the VSRs 3 to the respective unit pixels PIC are shorter than would be the case if only a single VSR 3 was used, the wiring capacitances of the signal lines L1 and L2 from the VSRs 3 to the respective unit pixels PIC become smaller. Accordingly, it is possible to shorten the time from the output of the transfer signals and the selection signals to the output of the pixel signals in the solid-state imaging device 14a.

In addition, a second chip 20a of the solid-state imaging device 14a includes two CDS/ADCs 4, two memories 5, and two HSRs 6 on two sides of the projection region (e.g., upper edge and lower edge) with the projection region 2a interposed therebetween. Specifically, the CDS/ADCs 4, the memories 5, and the HSRs 6 are disposed on opposing sides of the projection region 2a and extend in the direction parallel to the line direction (row direction) of the unit pixels PIC.

The CDS/ADC 4, the memory 5, and the HSR 6 provided on one side (e.g., lower edge) of the projection region 2a process the pixel signals output on the even-numbered lines.

The CDS/ADC 4, the memory 5, and the HSR 6 on the other side (e.g., upper edge) of the projection region 2a process the pixel signals output from the unit pixels PIC on the odd-numbered lines.

Therefore, the solid-state imaging device 14a may process the pixel signals in parallel by using two sets of the CDS/ADC 4, memory 5, and HSR 6. Accordingly, the solid-state imaging device 14a may reduce the time required for the signal process on the pixel signal by approximately half.

Next, the solid-state imaging device 14b according to Modified Example 2 is described. As illustrated in FIG. 7, the solid-state imaging device 14b has the same configuration with the solid-state imaging device 14a except that a first chip 10b includes analog circuits 30, and a second chip 20b includes logic circuits 40.

The analog circuits 30 include booster circuits that supply voltages to the VSRs 3. The analog circuits 30 are disposed on two sides of the pixel array 2 with the pixel array 2 interposed therebetween. Specifically, the analog circuits 30 are disposed on both sides of the pixel array 2 in the column direction of the unit pixels PIC.

In this manner, in the solid-state imaging device 14b, the analog circuits 30 are provided in vacant spaces on which the CDS/ADC 4, the memory 5, and the HSR 6 would otherwise be provided in a one-chip configuration.

Accordingly, in the solid-state imaging device 14b, since the analog circuits 30, which would generally be provided outside the chip in a one-chip configuration, may be provided in the first chip 10b, and the size of the entire apparatus in which the solid-state imaging device 14b is provided may be reduced.

In addition, signal processing circuits such as the ISP 15 (see FIG. 1) are included in the logic circuits 40. The logic circuits 40 are disposed on two sides of the projection region (e.g., left-page side and right-page side) with the projection region 2a interposed therebetween. Specifically, the logic circuits 40 are disposed on the both sides of the projection region 2a in the line direction of the unit pixels PIC.

In this manner, in the solid-state imaging device 14b, the logic circuits 40 are provided on the vacant spaces on which the VSRs 3 and the like would be provided in a one-chip configuration. Accordingly, in the solid-state imaging device 14b, since the logic circuits 40, which would otherwise be provided outside the chip in a one-chip configuration, are be provided in the second chip 20b, the size of the entire apparatus in which the solid-state imaging device 14b is provided may be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a first chip that includes a pixel array in which a plurality of photodiodes disposed in a two-dimensional array, and each photodiode generates a pixel signal corresponding to a charge generated by photoelectric conversion in the photodiode; and
a second chip in a stacked arrangement with the first chip, and including a memory unit configured to store the pixel signals generated by the plurality of photodiodes on the first chip, the memory unit being located outside a projection region defined by a projection, in a stacking direction of the first and second chips, of the area of the pixel array onto a surface of second chip.

2. The device according to claim 1, wherein the first chip includes a through electrode that penetrates the first chip in the stacking direction.

3. The device according to claim 1, wherein the first chip includes a vertical shift register disposed on both ends of the first chip with the pixel array interposed therebetween, each vertical shift register configured to generate transfer and selection signals for one half of the pixel array.

4. The device according to claim 1, wherein the second chip includes signal processing circuits which perform signal processing on the pixel signal, the signal processing circuits being disposed on two opposed sides of the projection region such a portion of the signal processing circuits is between the projection region and the memory unit.

5. The device according to claim 1, wherein the memory unit is a Dynamic Random Access Memory (DRAM).

6. A solid state imaging device, comprising:
a first chip that includes a pixel array, each pixel in the array generating a pixel signal corresponding to an amount of light incident on the pixel;
a vertical shift register on the first chip, adjacent to the pixel array, and configured to generate row selection signals for the pixel array;
a second chip in a stacked arrangement with the first chip and including an analog-to digital converter (ADC) unit that converts the pixel signals from the pixel array to digital pixel signals;
a memory unit on the second chip configured to store digital pixel signals, the memory unit being disposed on the second chip outside of a projection region of the pixel array, the projection region being defined by a projection, in a stacking direction of the first and second chips, of the area of the pixel array on to a surface of the second chip; and
a plurality of through electrodes that penetrate the first chip in the stacking direction and electrically connect to the second chip.

7. The solid state imaging device according to claim 6, wherein the vertical shift register has a first portion disposed along a first side of the pixel array, and a second portion disposed along a second side of the pixel array opposite the first side.

8. The solid state imaging device according to claim 7, wherein the first portion of the vertical shift register is configured to generate row selection signals for one half of the pixel array and the second portion of the vertical shift register is configured to generate row selection signals for the other half of the pixel array.

9. The solid state imaging device according to claim 6, wherein the memory unit has a first portion disposed along a first side of the projection region and a second portion disposed along a second side of the projection region opposite the first side.

10. The solid state imaging device according to claim 9, wherein the first portion of the memory unit is configured store digital pixel signals from one half of the pixel array and the second portion of the memory unit is configured to store digital pixel signals from the other half of the pixel array.

11. The solid state imaging device according to claim 6, wherein each pixel in the pixel array comprises two photodiodes.

12. The solid-state image device according to claim 6, wherein the second chip includes a horizontal shift register that is configured to provide timing signals to the ADC unit and the memory unit.

13. The solid state image device according to claim 6, wherein an electrical connection between the second chip and a through electrode that penetrates the first chip in the stacking direction is formed by a solder bump.

14. The device according to claim 6, wherein the memory unit is a Dynamic Random Access Memory (DRAM).

15. A solid state imaging device, comprising:
a first chip that includes a pixel array that includes a matrix of pixel units, each pixel unit including a photodiode that converts light to a pixel signal;
a second chip in a stacked arrangement with the first chip and including a storage unit that stores pixel signals, the storage unit being positioned outside a projection region of the pixel array, the projection region being defined by a projection, in a stacking direction of the first and second chips, of the area of the pixel array on to a surface of the second chip; and
a light shielding film covering the first chip outside of the pixel array.

16. The solid state imaging device according to claim 15, wherein the storage unit includes Dynamic Random Access Memory (DRAM).

17. The solid state imaging device according to claim 15, wherein a signal processing circuit is disposed on the second chip between the storage unit and the projection region.

18. The solid state imaging device according to claim 17, wherein the signal processing circuit comprises a correlated double sampling circuit.

19. The solid state imaging device according to claim 15, wherein an electrical connection between the first and second chips include a through electrode that penetrates the first chip in the stacking direction.

20. The solid state imaging device according to claim 15, wherein the storage unit comprises a first portion and a second portion that are disposed along opposite sides of the projection region.
